(19) United States
(12) Patent Application Publication
(10) Pub. No.: US 2011/0073979 A1
(43) Pub. Date: Mar. 31, 2011

(54) DETECTION ELEMENT

(75) Inventor: Yoshihiro OKADA, Kanagawa (JP)

(73) Assignee: FUJIFILM CORPORATION, Tokyo (JP)

(21) Appl. No.: 12/886,589

(22) Filed: Sep. 21, 2010

(30) Foreign Application Priority Data
Sep. 29, 2009 (JP) 2009-225285

(51) Int. Cl. H01L 31/105; H01L 31/0224

(52) U.S. Cl. 257/458; 257/466; 257/E31.124; 257/E31.061

(57) ABSTRACT

The present invention provides a detection element that can suppress leak current from an end face of a semiconductor layer. That is, of an n⁺ layer and a p⁺ layer respectively disposed between an i layer, in which an electric charge is generated as a result of being illuminated with light, and a pair of electrodes, an edge portion of a formed face of the p⁺ layer is formed further inward than that of the i layer.

### CROSS-REFERENCE TO RELATED APPLICATION

This application is based on and claims priority under 35 USC 119 from Japanese Patent Application No. 2009-225285 filed on Sep. 29, 2009, the disclosure of which is incorporated by reference herein.

### BACKGROUND OF THE INVENTION

1. Field of the Invention

The present invention relates to a detection element. Particularly, the present invention relates to a detection element where contact layers are disposed between a semiconductor layer, in which an electric charge is generated as a result of being illuminated with light and a pair of electrodes.

2. Description of the Related Art

In recent years, detection elements such as flat panel detectors (FPDs) that include an X-ray sensitive layer placed on a thin-film transistor (TFT) active matrix substrate and that can directly convert X-ray information into digital data, have been put to practical use. With these FPDs, images can be checked instantaneously in comparison to conventional imaging plates. Consequently, these FPDs have the advantage that video images can also be checked, and the spread of FPDs is rapidly progressing.

Various types of this kind of detection element have been proposed. For example, there are indirect conversion detection elements that first converts radiation into light with a scintillator such as CsI:Tl or GOS (Gd2O2S:Tb), then converts the converted light into an electric charge with a photodiode, and accumulates the electric charge.

In the photodiode used in this kind of detection element, an electrode that applies a bias voltage (hereinafter called a “bias electrode”) is disposed on one face of a PIN-type semiconductor layer formed by layering a p-type semiconductor layer, an i-type semiconductor layer, and an n-type semiconductor layer in order. Further, an electrode that collects the electric charge (hereinafter called a “collection electrode”) is disposed on the other face of the PIN-type semiconductor layer. The collection electrode collects the electric charge generated in the PIN-type semiconductor layer, and accumulates the electric charge as information representing an image.

Incidentally, sometimes leak failures occur in the photodiode. The rate of occurrence of these leak failures becomes higher dependent on the bias voltage. Further, it is understood that leak failures mainly occur on the end face of the photodiode.

In Japanese Patent Application Laid-Open (JP-A) No. 2008-244251, there is described a configuration where, for the purpose of suppressing leaks via the end face of a PIN-type semiconductor layer, the peripheral end face of a collection electrode is formed further inward than the peripheral end face of a PIN-type semiconductor layer.

However, this configuration cannot sufficiently suppress a leak current via the end face of the semiconductor layer.

### SUMMARY OF THE INVENTION

The present invention provides a detection element that can suppress a leak current via an end face of a semiconductor layer.

A first aspect of the invention is a detection element including: an insulating substrate on which a switch element for reading out an electric charge is disposed; a semiconductor layer, formed on the insulating substrate, that generates an electric charge as a result of being irradiated with electromagnetic waves; a pair of electrodes, one formed on either side of the semiconductor layer, that applies a voltage with respect to the semiconductor layer, and that collects the electric charge generated in the semiconductor layer; and a first and a second contact layer, each disposed between the semiconductor layer and the pair of electrodes, and electrically connected to the pair of electrodes and the semiconductor layer, wherein edge portions of the first contact layer are formed further inward than edge portions of the semiconductor layer.

In the detection element of the first aspect, the semiconductor layer, that generates an electric charge as a result of being irradiated with electromagnetic waves serving as a detection target, is formed on the insulating substrate on which the switch element for reading out an electric charge is disposed. Moreover, in the first aspect, the pair of electrodes, that apply a voltage with respect to the semiconductor layer and that collect the electric charge that has been generated in the semiconductor layer, are formed on both sides of the semiconductor layer.

Moreover, in the first aspect, the contact layers that electrically connect the pair of electrodes and the semiconductor layer are disposed between the semiconductor layer and the pair of electrodes. Moreover, in the first aspect, the edge portion of the forming face of at least one of the contact layers is formed further inward than the semiconductor layer.

In this manner, in the detection element according to the first aspect, the edge portion of the forming face of at least one of the contact layers disposed between the semiconductor layers and the pair of electrodes is formed further inward than the semiconductor layer. Consequently, the detection element pertaining to the first aspect can suppress a leak current via the end face of the semiconductor layer.

In a second aspect of the invention, in the first aspect, the edge portions of the first contact layer may be positioned further inward than the edge portions of the semiconductor layer by an amount equal to or greater than the layer thickness of the semiconductor layer.

In a third aspect of the invention, in the aspects described above, the semiconductor layer may be, at the side of the first contact layer, formed thinner between the edge portions of the semiconductor layer and the edge portions of the first contact layer than at a portion at which the first contact layer is formed.

In a fourth aspect of the invention, in the aspects described above, an electrode of the pair of electrodes at the side of the first contact layer may be formed in the same shape as the first contact layer.

In a fifth aspect of the invention, in the aspects described above, the semiconductor layer may be formed from an i-type semiconductor, the first contact layer may be formed from a p-type semiconductor, and the second contact layer may be formed from a n-type semiconductor.

In a sixth aspect of the invention, in the aspects described above, the semiconductor layer may be formed from an i-type semiconductor, the first contact layer may be formed from a n-type semiconductor, and the second contact layer may be formed from a p-type semiconductor.

According to the aspects of the present invention described above, the detection element of the present invention can suppress a leak current via the end face of the semiconductor layer.

### BRIEF DESCRIPTION OF THE DRAWINGS

Exemplary embodiments of the present invention will be described in detail based on the following figures, wherein:

FIG. 1 is a configuration diagram showing the overall configuration of a radiographic image detection device according to the exemplary embodiments;

FIG. 2 is a plan diagram showing the configuration of one pixel unit of a detection element according to the exemplary embodiments;

FIG. 3 is a cross-sectional diagram, taken along line A-A of FIG. 2, of the detection element according to of the exemplary embodiments;

FIG. 4 is a diagram for describing a process of manufacturing the detection element according to the exemplary embodiments;

FIG. 5 is an enlarged diagram showing an enlargement of a semiconductor layer and an upper electrode portion of the detection element according to the exemplary embodiments;

FIG. 6 is a schematic diagram showing the layer configuration of, the semiconductor layer that functions as a photodiode, the upper electrode, and a lower electrode, of the detection element according to the exemplary embodiments;

FIG. 7 is a schematic diagram showing the layer configuration of, the semiconductor layer that functions as a photodiode, the upper electrode, and the lower electrode, of a detection element according to another exemplary embodiment;

FIG. 8 is a cross-sectional diagram schematically showing the semiconductor layer and the upper electrode portion of the detection element according to the exemplary embodiments;

FIG. 9 is a cross-sectional diagram schematically showing a semiconductor layer and an upper electrode portion of a conventional detection element; and

FIG. 10 is a graph showing changes over time in percentages X of leak pixels, in the structure of the exemplary embodiments and in a conventional structure.

### DETAILED DESCRIPTION OF THE INVENTION

Exemplary embodiments of the present invention will be described below with reference to the drawings. A case where the present invention is applied to a radiographic image detection device 100, will be described below.

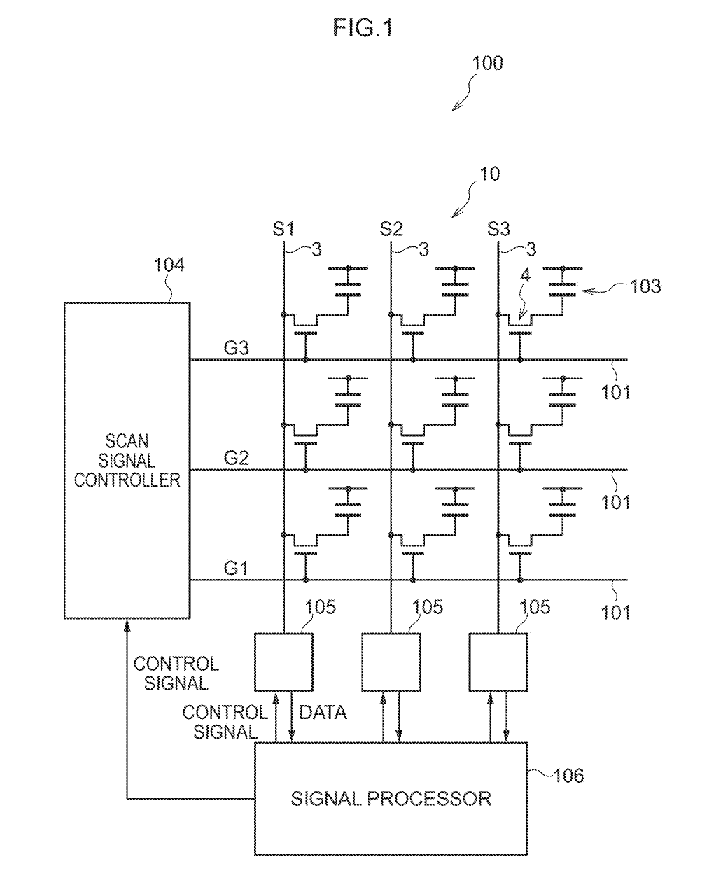

In FIG. 1, there is shown the overall configuration of the radiographic image detection device 100 according to an exemplary embodiment. Note that, a scintillator that converts radiation into light is omitted.

As shown in FIG. 1, the radiographic image detection device 100 according to the present exemplary embodiment includes a detection element 10 that detects the light that has been converted form the irradiated radiation by the scintillator.

The detection element 10 is equipped with an upper electrode, a semiconductor layer, and a lower electrode. Moreover, in the detection element 10, numerous pixels configured to include sensor components 103 and TFT switches 4 are two-dimensionally disposed. The sensor components 103 accumulate electric charges charged based on the received light that has been converted form the irradiated radiation by the scintillator. Further, the TFT switches 4 read out the electric charges that have been accumulated in the sensor components 103.

Further, in the detection element 10, plural scan lines 101 and plural signal lines 3 are disposed intersecting each other. The plural scan lines 101 switch the TFT switches 4 ON and OFF. The plural signal lines 3 read out the electric charges that have been accumulated in the sensor components 103.

In each of the signal lines 3, there flows an electrical signal corresponding to the electric charge amount accumulated in the sensor component 103, as a result of any of the TFT switches 4 connected to that signal line 3 being switched ON. Signal detection circuits 105 that detect the electrical signals flowing out to the signal lines 3 are connected to the signal lines 3. Further, a scan signal controller 104 that outputs control signals for switching the TFT switches 4 ON and OFF to each of the scan lines 101, is connected to each of the scan lines 101.

The signal detection circuits 105 include built-in amplifier circuits that amplify the inputted electrical signals for each of the signal lines 3. The signal detection circuits 105 amplify, with the amplifier circuits, the electrical signals inputted from the signal lines 3 and detect those electrical signals. Thus, the signal detection circuits 105 detect the electric charge amounts accumulated in the sensor components 103, as information of each pixel configuring an image.

A signal processor 106 that administers predetermined processing to the electrical signals detected in the signal detection circuits 105 is connected to the signal detection circuits 105 and the scan signal controller 104. The signal processor 106 outputs control signals indicating the timing of signal detection to the signal detection circuits 105, and outputs a control signal indicating the timing of the output of scan signals to the scan signal controller 104.

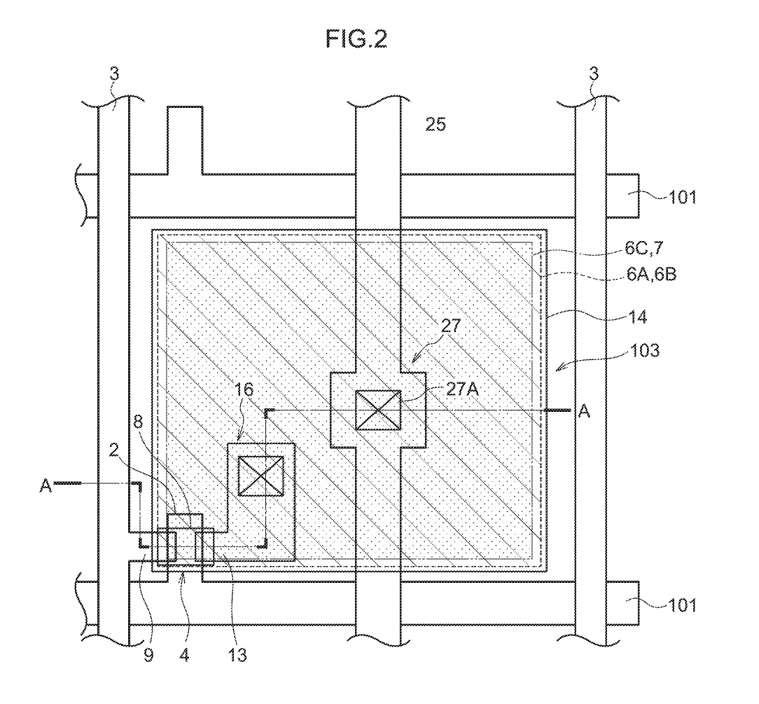

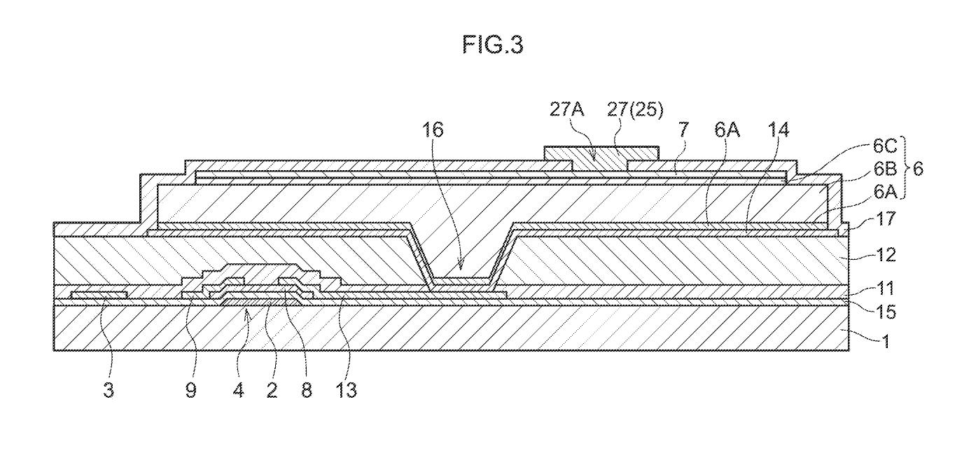

Next, the detection element 10 according to the present exemplary embodiment will be described in detail with reference to FIG. 2 and FIG. 3. FIG. 2 shows a plan diagram showing the structure of one pixel unit of the detection element 10 according to the present exemplary embodiment. FIG. 3 shows a cross-sectional diagram taken along line A-A of FIG. 2.

As shown in FIG. 3, in the detection element 10, the scan line 101 and a gate electrode 2 are formed on an insulating substrate 1, consisting of alkali-free glass. Further, the scan line 101 and the gate electrode 2 are connected (see FIG. 2). The line layer in which the scan line 101 and the gate electrode 2 are formed (hereinafter, this line layer will be called a “first signal line layer”) is formed using Al or Cu, or a layered film whose main component is Al or Cu. However, the material of the first line layer is not limited to these.

An insulating film 15 is formed on one face of the scan line 101 and the gate electrode 2, to cover the scan line 101 and the gate electrode 2. The site of the insulating film 15 positioned on the gate electrode 2 acts as a gate insulating film in the TFT switch 4. This insulating film 15 includes SiNₓ, for example. Further, the insulating film 15 is formed by chemical vapor deposition (CVD) film formation, for example.

A semiconductor active layer 8 is formed in the form of an island over the gate electrode 2 on the insulating film 15. This semiconductor active layer 8 is a channel portion of the TFT switch 4, and consists of an amorphous silicon film, for example.

On these layers, a source electrode 9 and a drain electrode 13 are formed. In the line layer in which the source electrode 9 and the drain electrode 13 are formed, the signal line 3 is formed together with the source electrode 9 and the drain electrode 13. The source electrode 9 is connected to the signal line 3 (see FIG. 2). The line layer in which the signal line 3 and the source electrode 9 are formed (hereinafter, this line layer will be called a “second signal line layer”) is formed using Al or Cu, or a layered film whose main component is Al or Cu. However, the material of the second line layer is not limited to these.

An impurity-doped semiconductor layer (not shown), formed by impurity-doped amorphous silicon or the like, is formed between the source electrode 9 and drain electrode 13 and the semiconductor active layer 8. The switching-use TFT switch 4 is configured by the source electrode 9, the drain electrode 13, the semiconductor active layer 8, and the impurity-doped semiconductor layer.

A TFT protective film layer 11 is formed to cover the semiconductor active layer 8, the source electrode 9, the drain electrode 13, and the signal line 3, on substantially the entire face of the region on the substrate 1 where the pixel is disposed (on substantially the entire region). This TFT protective film layer 11 consists of SiNₓ, for example, and is formed by CVD film formation, for example.

An applied interlayer insulating film 12 is formed on the TFT protective film layer 11. This interlayer insulating film 12 is formed in a film thickness of 1 μm to 4 μm by a low permittivity (permittivity εᵣ=2 to 4) photosensitive organic material (e.g., a positive-type photosensitive acrylic resin: a material where naphthoquinone-diazide positive-type photosensitizing agent is mixed together with a base polymer consisting of a copolymer of methacrylic acid and glycidyl methacrylate). In the detection element 10 according to the present exemplary embodiment, this interlayer insulating film 12 keeps the capacitance between metals placed above and below the interlayer insulating film 12 low. Further, usually, this material also has a function as a flattening film. This function as a flattening film also has the effect of flattening underlying bumps. The shape of a semiconductor layer 6 placed above is flattened by the interlayer insulating film 12, so a drop in absorption efficiency resulting from unevenness in the semiconductor layer 6 and an increase in a leak current can be suppressed. A contact hole 16 is formed in the interlayer insulating film 12 and in the TFT protective film layer 11, in a position opposing the drain electrode 13.

A lower electrode 14 of the sensor component 103 is formed on the interlayer insulating film 12 to fill in the contact hole 16 and cover the pixel region. This lower electrode 14 is connected to the drain electrode 13 of the TFT switch 4. As for the material of this lower electrode 14, there are virtually no restrictions on the material as long as it is electrically conductive when the semiconductor layer 6 is around 1 μm and thick. For this reason, it suffices for the lower electrode 14 to be formed using an electrically conductive metal such as an Al material or indium tin oxide (ITO).

When the film thickness of the semiconductor layer 6 is thin (around 0.2 μm to 0.5 μm), light absorption by the semiconductor layer 6 may not be sufficient. For this reason, in order to prevent an increase in a leak current resulting from light illumination of the TFT switch 4, the lower electrode 14 preferably consists of an alloy whose main component is a light-blocking metal or a layered film.

The semiconductor layer 6 that functions as a photodiode is formed on the lower electrode 14. In the present exemplary embodiment, a photodiode with a PIN structure formed by layering an n⁺ layer, an i layer, and a p⁺ layer (n⁺ amorphous silicon, amorphous silicon, and p⁺ amorphous silicon) is employed as the semiconductor layer 6. Consequently, the semiconductor layer 6 is formed by layering an n⁺ layer 6A, an i layer 6B, and a p⁺ layer 6C from the bottom. The i layer 6B functions as a semiconductor layer of the present invention, and generates an electric charge (free electron and free hole pair) as a result of being illuminated with light. The n⁺ layer 6A and the p⁺ layer 6C function as contact layers, and electrically connect the lower electrode 14 and an upper electrode 7 and the i layer 6B.

In the present exemplary embodiment, the p⁺ layer 6C is formed smaller than the n⁺ layer 6A and the i layer 6B. Further, in the present exemplary embodiment, an edge portion of a forming face of the p⁺ layer 6C is caused to recede further back than edge portions of forming faces of the n⁺ layer 6A and the i layer 6B such that the edge portion of the forming face of the p⁺ layer 6C is formed further inward than the edge portions of the forming faces of the n⁺ layer 6A and the i layer 6B.

Further, in the present exemplary embodiment, the lower electrode 14 is made larger than the semiconductor layer 6. When the film thickness of the semiconductor layer 6 is thin (e.g., equal to or less than 0.5 μm), it is preferable to place a light-blocking metal and cover the TFT switch 4 for the purpose of preventing light incidence on the TFT switch 4.

Further, in the present exemplary embodiment, in order to suppress light entry into the TFT switch 4, resulting from diffuse reflection of light inside the radiographic image detection device 100, a distance of 5 μm or greater is secured between the channel portion of the TFT switch 4 and the edge portion of the lower electrode 14 including a light-blocking metal.

An upper electrode 7 is formed on the semiconductor layer 6. For this upper electrode 7, a material with high light transmittance such as ITO or indium zinc oxide (IZO), for example, is used. In the present exemplary embodiment, the upper electrode 7 is formed in the same size as the p⁺ layer 6C of the semiconductor layer 6.

A protective insulating film 17 is formed on the interlayer insulating film 12, the semiconductor layer 6 and the upper electrode 7, to have an opening 27A in a portion thereof corresponding to the upper electrode 7. Similar to the TFT protective film layer 11, the protective insulating film 17 consists of SiNₓ, for example. Further, the protective insulating film 17 is formed by CVD film formation, for example.

A common electrode line 25 is formed on this protective insulating film 17. The common electrode line 25 is formed by Al or Cu, or an alloy or a layered film whose main component is Al or Cu. A contact pad 27 is formed in the common electrode line 25 near the opening 27A. The common electrode line 25 is electrically connected to the upper electrode 7 via the opening 27A in the protective insulating film 17 by the contact pad 27.

In the detection element 10 formed in this manner, a protective film is formed by an insulating material with low light absorption on the protective insulating film 17 as needed. A scintillator consisting of GOS or the like is adhered to the top surface of the protective film using an adhesive resin with low light absorption.

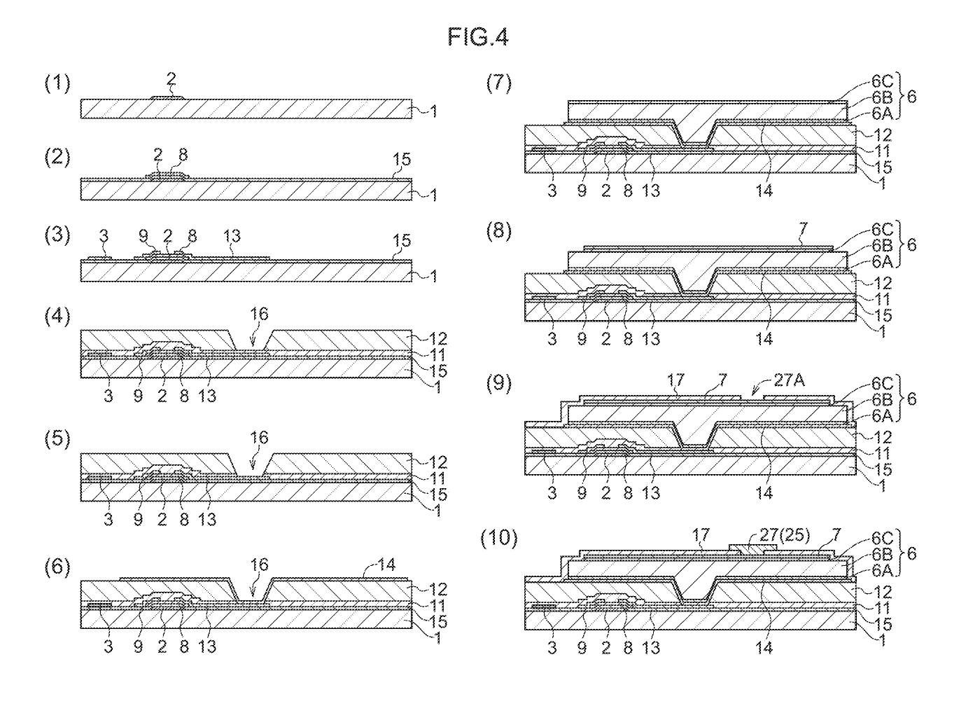

Next, one example of a process of manufacturing the detection element 10 according to the exemplary embodiment will be described with reference to (1) to (10) of FIG. 4.

First, the gate electrode 2 and the scan line 101 (not shown) are formed as the first signal line layer on the substrate 1 ((1) of FIG. 4). This first signal line layer includes a layered film with a barrier metal layer having a high melting point metal or a low resistance metal such as Al or an Al alloy. The first signal line layer is deposited on the substrate 1, by sputtering such that its film thickness is around 100 to 300 nm. Thereafter, patterning of the resist film is performed by a photolithography technique. Thereafter, the metal film is patterned by wet etching resulting from an etchant for Al or dry etching. Thereafter, the resist is removed, whereby the first signal line layer is completed.

Next, the insulating film 15, the semiconductor active layer 8, and the impurity-doped semiconductor layer (not shown) are sequentially deposited on the first signal line layer ((2) of FIG. 4). The insulting film 15 consists of SiNₓ, and has a film thickness of 200 to 600 nm. Further, the semiconductor active layer 8 consisting of amorphous silicon and has a film thickness of around 20 to 200 nm. Moreover, the impurity-doped semiconductor layer consisting of impurity-doped amorphous silicon and has a film thickness of around 10 to 100 nm. The impurity-doped semiconductor layer is deposited by plasma-chemical vapor deposition (P-CVD). Thereafter, like the first signal line layer, patterning of the resist is performed by a photolithography technique. Thereafter, a channel region is formed by selectively dry-etching the semiconductor active layer 8.

Next, the signal line 3, the source electrode 9, and the drain electrode 13 are formed as the second signal line layer on the insulating film 15 and the semiconductor active layer 8 ((3) of FIG. 4). This second signal line layer, like the first signal line layer, consisting of a layered film with a barrier metal layer having a high melting point metal or a low resistance metal, such as Al or an Al alloy, or a single layer of a high melting point metal film such as Mo. The film thickness of the second signal line layer is around 100 to 300 nm. The second signal line layer, like the first signal line layer, is patterned by a photolithography technique. The patterning may be performed by wet etching resulting from an etchant for Al or dry etching. At that time, the insulating film 15 is not removed because etching is selectively employed.

Next, the TFT protective film layer 11 and the interlayer insulating film 12 are sequentially formed on top of the layers that have been formed as described above ((4) of FIG. 4). There are cases where the TFT protective film layer 11 and the interlayer insulating film 12 are stand-alone inorganic materials, cases where the TFT protective film layer 11 and the interlayer insulating film 12 are formed by layering a protective insulating film consisting of an inorganic material and an interlayer insulating film consisting of an organic material, and cases where the TFT protective film layer 11 and the interlayer insulating film 12 are formed by a single layer of an interlayer insulating film consisting of an organic material. In the present exemplary embodiment, the TFT protective film layer 11 and the interlayer insulating film 12 have a layered structure including the photosensitive interlayer insulating film 12 and the TFT protective film layer 11 consisting of an inorganic material. This is to suppress electrostatic capacitance between the underlying common electrode line 25 and the lower electrode 14 and to stabilize the characteristics of the TFT switch 4. For example, the TFT protective film layer 11 is formed by CVD film formation. Next, the interlayer insulating film 12 is formed by applying, prebaking, thereafter exposing, developing, and firing a photosensitive applied material.

Next, the TFT protective film layer 11 is patterned by a photolithography technique ((5) of FIG. 4). When the TFT protective film 11 is not placed, this process is not necessary.

Next, a metal material such as an Al material or ITO is deposited by sputtering on the top of this layer. The film thickness is around 20 to 200 nm. Next, patterning is performed by a photolithography technique, patterning is performed by wet etching resulting from an etchant for metal or dry etching, and the lower electrode 14 is formed ((6) of FIG. 4).

Next, each of the n⁺, i, and p⁺ layers are deposited in order from the bottom by CVD to form the n⁺ layer 6A, the i layer 6B, and the p⁺ layer 6C of the semiconductor layer 6 ((7) of FIG. 4). The film thickness of the n⁺ layer is 50 to 500 nm, the film thickness of the i layer is 0.2 to 2 μm, and the film thickness of the p⁺ layer is 50 to 500 nm. The semiconductor layer 6 is completed by layering each layer in order, patterning the semiconductor layer 6 by a photolithography technique, and selectively etching the underlying interlayer insulating layer 12 by dry etching or wet etching.

Here, the semiconductor layer 6 is layered in the order of n⁺, i, and p⁺. However, the semiconductor layer 6 may also be layered in the order of p⁺, i, and n⁺ to form a PIN diode.

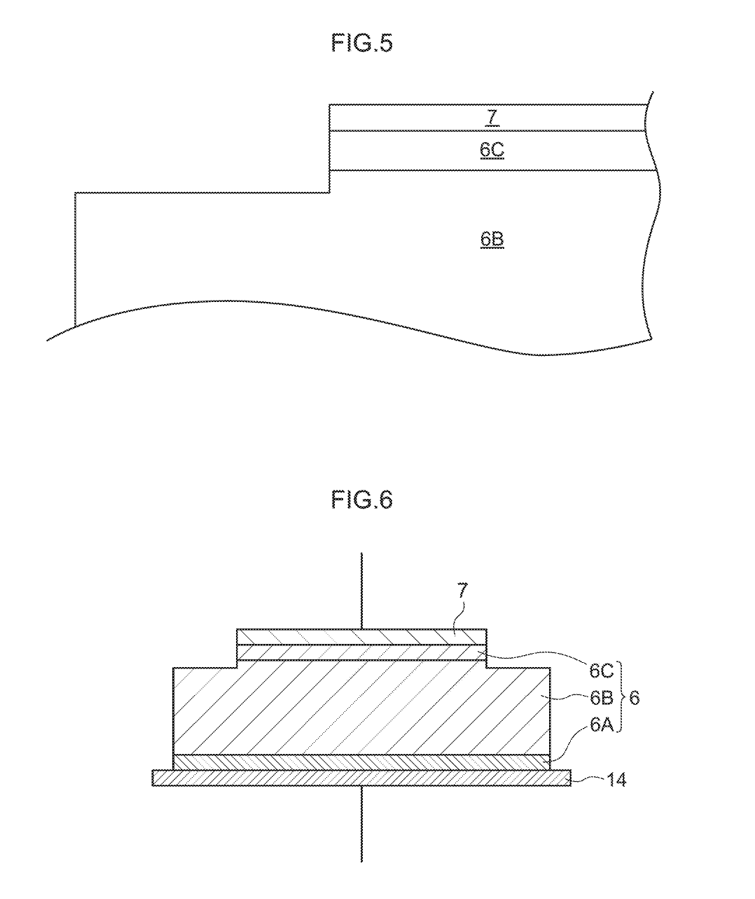

Next, the upper electrode 7 is formed ((8) of FIG. 4). The upper electrode 7 is formed by depositing, by sputtering, a transparent electrode material such as ITO on top of the layer that has been formed as described above. The film thickness of the upper electrode 7 is around 20 nm to 200 nm. Next, patterning is performed by a photolithography technique, and the upper electrode 7 is patterned by wet etching resulting from an etchant for ITO or dry etching. Thereafter, the upper electrode 7 is used as a mask to selectively etch the semiconductor layer 6. Moreover, the entire portion of the p⁺ layer 6C and the top surface of the i layer 6B at the periphery of the semiconductor layer 6 are removed. Thus, as shown in FIG. 5, the top surface portion of the i layer 6B is removed across its end face from the peripheral portion of the p⁺ layer 6C. Moreover, the thickness of the i layer 6B is thin at the peripheral portion of the p⁺ layer 6C in comparison to the p⁺ layer 6C portion.

Next, the protective insulating film 17 consisting of an SiNx film is deposited by CVD or the like, to cover the upper electrode 7. Thereafter, patterning is performed by a photolithography technique, patterning is performed by dry etching, and the opening 27A is formed ((9) of FIG. 4). Here, SiNx deposited by CVD film formation is described as one example of a method of forming the protective insulating film 17. However, another material can be applied as long as it is an insulating material, and the material is not limited to SiNx.

Next, the common electrode line 25 is formed ((10) of FIG. 4). The common electrode line 25 and the contact pad 27 are deposited, by sputtering a metal material such as Al or Cu, or an alloy whose main component is Al or Cu, on the top of the layer that has been formed as described above. The film thickness of the common electrode line 25 is around 100 nm to 500 nm. The common electrode line 25 and the contact pad 27 are formed by performing patterning by a photolithography technique, and patterning by wet etching resulting from an etchant for metal or dry etching.

A scintillator consisting of GOS is adhered, using an adhesive resin or the like, to the top surface of the detection element 10 that has been formed in this manner.

Next, the principle of operation of the radiographic image detection device 100 of the structure described above will be described.

When the detection element 10 is irradiated with X-rays, the X-rays with which the detection element 10 has been irradiated are absorbed by the scintillator and converted into visible light. The detection element 10 may be irradiated with the X-rays from its front side or its back side. The semiconductor layer 6 of the sensor components 103 placed in an array on the substrate 1 is illuminated with the light, that has been converted into visible light by the scintillator.

The semiconductor layer 6 is separated into each pixel unit and, is disposed in the detection element 10. A predetermined bias voltage is applied to the semiconductor layer 6 from the upper electrode 7 via the common electrode line 25, and when the semiconductor layer 6 is illuminated with light, an electric charge is generated inside the semiconductor layer 6. For example, when the semiconductor layer 6 has a PIN structure, a negative bias voltage is applied to the upper electrode 7. When the film thickness of the i layer 6B is about 1 μm, the applied bias voltage is about −5 V to −10 V.

Here, in the present exemplary embodiment, the edge portion of the forming face of the p⁺ layer 6C is caused to recede further back than the edge portions of the forming faces of the n⁺ layer 6A and the i layer 6B such that the edge portion of the forming face of the p⁺ layer 6C is formed further inward than the edge portions of the forming faces of the n⁺ layer 6A and the i layer 6B.

In FIG. 6, there is shown a schematic diagram showing the layer configuration of the semiconductor layer 6 that functions as the photodiode of the detection element 10, the upper electrode 7, and the lower electrode 14.

In the detection element 10, because the edge portion of the forming face of the p⁺ layer 6C is caused to recede further back than the edge portions of the forming faces of the n⁺ layer 6A and the i layer 6B, the effective distance between the p⁺ layer 6C and the n⁺ layer 6A becomes larger. Thus, the intensity of the electric field applied to the end face of the i layer 6B is suppressed, and the occurrence of leak failures via the end face of the i layer 6B can be suppressed. The recession amount by which the forming face of the p⁺ layer 6C is caused to recede with respect to the forming surfaces of the n⁺ layer 6A, and the i layer 6B is preferably equal to or greater than the layer thickness of the i layer 6B in order to suppress the intensity of the electric field applied to the end face of the i layer 6B. For example, when the layer thickness of the i layer 6B is about 1 μm, the edge portion of the forming face of the p⁺ layer 6C is preferably caused to recede about 3 μm to 5 μm considering that patterning error is about 2 μm to 4 μm.

Further, the top surface portion of the i layer 6B is removed across the edge portion from the peripheral portion of the p⁺ layer 6C, so that the thickness of the i layer 6B is thin at the peripheral portion of the p⁺ layer 6C in comparison to the p⁺ layer 6C portion. In this manner, because the top surface portion of the i layer 6B is removed across the edge portion from the peripheral portion of the p⁺ layer 6C, p⁺ remaining on the top surface of the i layer 6B is removed. For this reason, the occurrence of a leak current via the end face can is suppressed.

When the semiconductor layer 6 is not illuminated with light in a state where the bias voltage is applied thereto, only a current equal to or less than several pA/mm² flows therein. On the other hand, when the semiconductor layer 6 is illuminated with light (1 μW/cm²) in a state where the bias voltage is applied thereto, a light current of about several to several tens nA/mm² is generated. This generated electric charge is collected by the lower electrode 14. The lower electrode 14 is connected to the drain electrode 13 of the TFT switch 4. Further, the source electrode 9 of the TFT switch 4 is connected to the signal line 3. At the time of image detection, a negative bias is applied to the gate electrode 2 of the TFT switch 4 and is held in an OFF state, and the electric charge collected in the lower electrode 14 is accumulated.

At the time of image detection, ON signals (+10 V to 20 V) are sequentially applied via the scan lines 101 to the gate electrodes 2 of the TFT switches 4. Thus, the TFT switches 4 are sequentially switched ON, whereby electrical signals corresponding to the electric charge amounts accumulated in the lower electrodes 14 flow out to the signal lines 3. The signal detection circuits 105 detect, as information of each pixel configuring the image, the electric charge amounts accumulated in the sensor components 103 on the basis of the electrical signals flowing out to the signal lines 3. Thus, the image information representing the image represented by the X-rays with which the detection element 10 has been irradiated, is obtained.

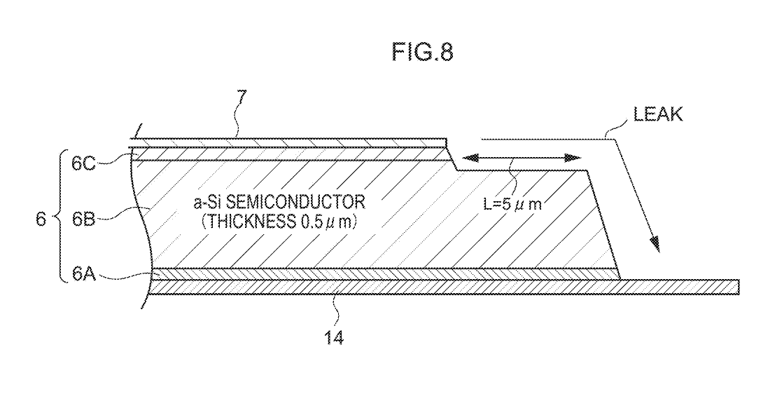

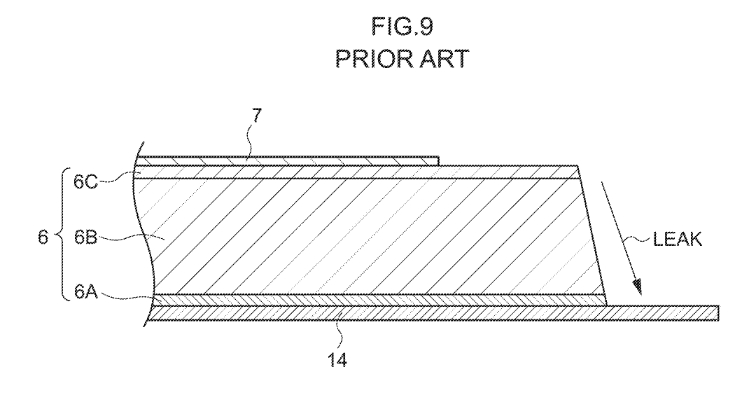

Here, the number of leak pixels in which a leak occurs was measured over time, in a case where the semiconductor layer 6 of the detection element 10 was formed as in the present exemplary embodiment (FIG. 8), and in a case where the semiconductor layer of the detection element was formed as in a conventional structure (FIG. 9). In the present exemplary embodiment, the detection element 10 was formed such that the edge portion of the forming face of the p⁺ layer 6C was caused to recede further back than the edge portions of the forming faces of the n⁺ layer 6A and the i layer 6B, and the top surface of the top surface portion of the i layer 6B was removed across the edge portion from the peripheral portion of the p⁺ layer 6C, to make the thickness of the i layer 6B thin at the peripheral portion of the p⁺ layer 6C in comparison to the p⁺ layer 6C portion (FIG. 8). In the conventional structure, the detection element was formed such that the p⁺ layer 6C was in the same range as the n⁺ layer 6C and the i layer 6B (FIG. 9). The thickness of the i layer 6B was 0.5 μm. Further, the recession amount L of the edge portion of the forming face of the p⁺ layer 6C with respect to the edge portions of the forming faces of the n⁺ layer 6A and the i layer 6B was 5 μm.

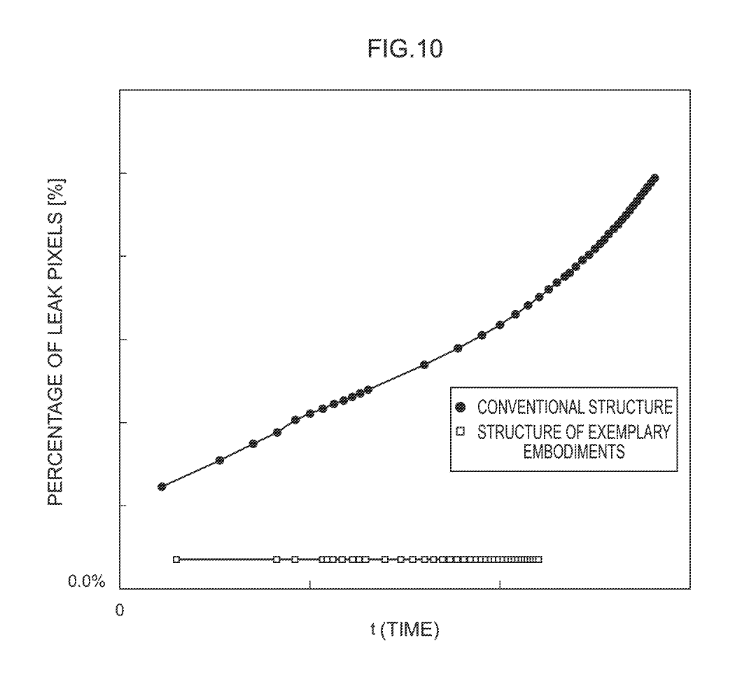

In FIG. 10, there are shown changes over time in percentages X of leak pixels with respect to the total number of pixels in the structure of the present exemplary embodiment (FIG. 8) and in the conventional structure (FIG. 9).

As shown in FIG. 10, in the structure of the present exemplary embodiment, there were few leak pixels as compared to in the conventional structure. Further, in the conventional structure, there was seen a change where the leak pixels increase over time. On the other hand, in the structure of the present exemplary embodiment, an increase in the leak pixels over time was not seen.

In the exemplary embodiment described above, there has been described a case where the edge portion of the forming face of the p⁺ layer 6C is caused to recede further back than the edge portions of the forming face of the n⁺ layer 6A and the i layer 6B, such that the edge portion of the forming face of the p⁺ layer 6C is formed further inward than the edge portions of the forming faces of the n⁺ layer 6C and the i layer 6B. However, the present invention is not limited to this. For example, in an alternative exemplary embodiment, the p⁺ layer 6C and the i layer 6B may be made the same size and the edge portion of the forming face of the n⁺ layer 6A may be caused to recede further back than the edge portions of the forming faces of the i layer 6B and the p⁺ layer 6C, such that the edge portion of the forming face of the n⁺ layer 6A is formed further inward than the edge portions of the forming faces of the i layer 6B and the p⁺ layer 6C. Further, in an alternative exemplary embodiment, the edge portions of the forming faces of both the n⁺ layer 6A and the p⁺ layer 6C may also be caused to recede further back than the edge portion of the forming face of the i layer 6B.

Further, in the exemplary embodiment described above, there has been described a case where each of the n⁺, i, and p⁺ layers are deposited, patterning is performed by a photolithography technique to form the n⁺ layer 6A, the i layer 6B, and the p⁺ layer 6C, a transparent electrode material is deposited on top of that, the upper electrode 7 is patterned by wet etching or dry etching, and thereafter the upper electrode 7 is used as a mask to remove the entire portion of the p⁺ 6C and the top surface of the i layer 6B. However, the present invention is not limited to this. For example, in another exemplary embodiment, each of the n⁺ and i layers may be deposited, patterning may be performed by a photolithography technique to first form the n⁺ layer 6A and the i layer 6B of the semiconductor layer 6, the p⁺, and the transparent electrode material may be deposited on top of that, and the p⁺ layer 6C and the upper electrode 7 may be patterned. In this exemplary embodiment, the step of removing the peripheral portion of the p⁺ layer 6C becomes unnecessary because the p⁺ layer 6C and the upper electrode 7 are formed in order. In this exemplary embodiment also, the upper electrode 7 is formed in the same size as the p⁺ layer 6C of the semiconductor layer 6.

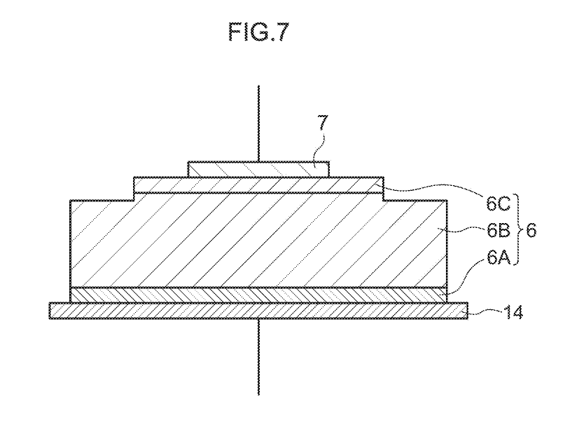

Further, in the exemplary embodiment described above, there has been described a case where the upper electrode 7 is formed in the same size as the p⁺ layer 6C of the semiconductor layer 6. However, the present invention is not limited to this. For example, in another exemplary embodiment, the p⁺ layer 6C and the upper electrode 7 may also be formed in different steps so that, as shown in FIG. 7, the upper electrode 7 is formed smaller than the p⁺ layer 6C of the semiconductor layer 6.

Further, in the exemplary embodiment described above, there has been described a case where alkali-free glass is used as the substrate 1. However, the present invention is not limited to this. For example, the substrate 1 may also be formed using an insulator such as polyimide. The material of the substrate is not limited to these.

Further, in the exemplary embodiment described above, there has been described a case where the present invention is applied to the radiographic image detection device 100 that detects an image by detecting X-rays. However, the present invention is not limited to this. For example, the electromagnetic waves serving as the detection target may also be any of visible light, ultraviolet rays, or infrared rays.

In addition, the configuration of the radiographic image detection device 100 (see FIG. 1) and the configuration of the detection element 10 (FIG. 2 to FIG. 8) that have been described in the exemplary embodiments described above are examples, and it goes without saying that they may be appropriately altered within a scope that does not depart from the gist of the present invention.

What is claimed is:

1. A detection element comprising:
an insulating substrate on which a switch element for reading out an electric charge is disposed;
a semiconductor layer, formed on the insulating substrate, that generates an electric charge as a result of being irradiated with electromagnetic waves;
a pair of electrodes, one formed on either side of the semiconductor layer, that applies a voltage with respect to the semiconductor layer, and that collects the electric charge generated in the semiconductor layer; and
a first and a second contact layer, each disposed between the semiconductor layer and the pair of electrodes, and electrically connected to the pair of electrodes and the semiconductor layer, wherein edge portions of the first contact layer are formed further inward than edge portions of the semiconductor layer.

2. The detection element according to claim 1, wherein the edge portions of the first contact layer are positioned further inward than the edge portions of the semiconductor layer by an amount equal to or greater than the layer thickness of the semiconductor layer.

3. The detection element according to claim 1, wherein the semiconductor layer is, at the side of the first contact layer, formed thinner between the edge portions of the semiconductor layer and the edge portions of the first contact layer than at a portion at which the first contact layer is formed.

4. The detection element according to claim 1, wherein an electrode of the pair of electrodes at the side of the first contact layer is formed in the same shape as the first contact layer.

5. The detection element according to claim 1, wherein:
the semiconductor layer is formed from an i-type semiconductor;
the first contact layer is formed from a p-type semiconductor; and
the second contact layer is formed from an n-type semiconductor.

6. The detection element according to claim 1, wherein:
the semiconductor layer is formed from an i-type semiconductor;
the first contact layer is formed from an n-type semiconductor; and
the second contact layer is formed from a p-type semiconductor.
